(19) United States
(12) Patent Application Publication
(10) Pub. No.: US 2010/0107026 A1
(43) Pub. Date: Apr. 29, 2010

(54) Semiconductor device having built-in self-test circuit and method of testing the same

(75) Inventor: Yoshihiro Nakamura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/588,152

(22) Filed: Oct. 6, 2009

(30) Foreign Application Priority Data
Oct. 24, 2008 (JP) 274448-2008

(51) Int. Cl. G01R 31/3187; G06F 11/00

(52) U.S. Cl. 714/733; 714/E11.002

(57) ABSTRACT

A semiconductor device includes circuits to be tested, an input terminal for receiving a tester clock signal from outside, a built-in self-test (BIST) circuit for logically testing the circuit at every cycle of a tester clock signal, and an output terminal for outputting a test result signal representing a result of testing performed in the BIST circuit. Before generating a test result signal, the BIST circuit generates a marker signal, whose phase is identical to the phase of the test result signal, instead of the test result signal.

### INCORPORATION BY REFERENCE

This application is based upon and claims the benefit of priority from Japanese Patent Application No. 2008-274448 which was filed on Oct. 24, 2008, the disclosure of which is incorporated herein in its entirety by reference.

### BACKGROUND OF THE INVENTION

1. Field of the Invention

The present invention relates to a semiconductor device and a method of testing the same, and more particularly, to a semiconductor device having a built-in self-test circuit and a method of testing the same.

2. Description of Related Art

To make it easy to test semiconductor devices, semiconductor devices are each provided with a built-in self-test (BIST) circuit for detecting faults in them. Patent document 1 listed below, for example, discloses a semiconductor device having a BIST circuit which can identify a fail-data address and a fail-data bit without causing the testing time or cost to increase and which can easily test an AC characteristic, for example, an access time characteristic of a circuit. The BIST circuit compares test data written to a memory device and the data read from the memory device, when an error is detected, outputs the fail data read from the memory device and an address signal indicating the fail-data address.

Patent document 2 listed below discloses a method of diagnosing a RAM and an LSI which makes it possible to diagnose a RAM included in an LSI at high speed using a low-speed tester or a low-speed BIST circuit. The LSI includes a parallel/serial conversion circuit and a serial/parallel conversion circuit. The parallel/serial conversion circuit converts t-bit parallel data which is provided for use in testing the RAM and whose operating speed is lit times the operating clock frequency of the LSI into write data to be written, at the operating clock frequency of the LSI, to the RAM. The serial/parallel conversion circuit converts t-bit data read from the RAM at the operating clock frequency of the LSI into t-bit parallel data whose operating speed is 1/t times the operating clock frequency of the LSI.

[Patent Document 1] Japanese Patent Application Laid Open No. H 11-39226

[Patent Document 2] Japanese Patent Application Laid Open No. 2001-110200

### SUMMARY

Analysis made in connection with the present invention follows.

In recent years, LSIs have been remarkably growing in scale and operating speed. Keeping pace with the trend, the cost of testing LSIs has been increasing. Shortening the time required to test LSIs is one way of reducing the cost of testing LSIs. Namely, making it possible to successively test LSIs using a high-speed clock signal results in shortening the time required to test LSIs and reducing the cost of testing them.

According to the semiconductor device disclosed in the patent document 1, however, when outputting, upon detection of an error, the fail data read from memory and an address signal indicating the fail-data address, it is necessary to interrupt the error detection operation and output the data and the address signal from a scan circuit. It is therefore not possible to perform an error detection operation at every cycle of a clock signal, so that the testing time cannot be reduced beyond a certain extent.

The LSI disclosed in the patent document 2 includes a parallel/serial conversion circuit and a serial/parallel conversion circuit and reads a fault detection signal at low speed. It is therefore possible to perform successive fault detection operations using a clock signal for testing. When the clock signal is made faster, however, it becomes increasingly difficult to determine the timing for reading a fault detection signal from the parallel conversion circuit. Namely, supplying a clock signal to inside the LSI from an external tester via a clock pin makes it possible to read a fault detection signal in synchronization with the clock signal. In this case, however, the delay time involved in reading the fault detection signal is dependent, for example, on the LSI structure and the wiring length between the tester and the LSI, so that it is not constant. Therefore, when the clock signal is made faster, it becomes difficult to accurately determine the timing of the fault detection signal, so that performing the test becomes increasingly difficult.

The semiconductor device according to one exemplary aspect of the present invention includes circuits to be tested, an input terminal for inputting an external tester clock signal, a built-in self-test circuit for logically testing the circuit to be tested at every cycle of the tester clock signal, and an output terminal for outputting a test result signal representing a result of testing performed by the built-in self-test circuit. In the semiconductor device, the built-in self-test circuit has a function of generating, before generating the test result signal, a marker signal instead of the test result signal, the marker signal having a phase identical to the phase of the test result signal.

A method of testing a semiconductor device according to another exemplary aspect of the present invention is used to test a semiconductor device which includes a built-in self-test circuit for testing a circuit to be tested in synchronization with a tester clock signal inputted from outside and outputting a test result signal representing a result of testing performed in the built-in self-test circuit to outside. According to the method, before the test result signal is generated, a marker signal having a phase identical to the phase of the test result signal is generated instead of the test result signal in the built-in self-test circuit.

A method of testing a semiconductor device according to still another exemplary aspect of the present invention is used to test a semiconductor device which includes a circuit to be tested, an input terminal for inputting a tester clock signal from a test equipment, a built-in self-test circuit for logically testing the circuit to be tested in synchronization with the tester clock signal, and an output terminal for outputting a test result signal representing a result of testing performed by the built-in self-test circuit. The method includes supplying the tester clock signal to the input terminal by the test equipment, before generating the test result signal, generating a marker signal instead of the test result signal by the built-in self-test circuit, the marker signal having a phase identical to the phase of the test result signal, and receiving the marker signal from the output terminal and determining the phase of the test result signal by the test equipment.

According to the exemplary aspects, the marker pulse signal is generated before the generation of a test result signal, so that the timing for reading the test result signal can be accurately determined. It is therefore possible to successively perform checking with an expected value and faulty-cycle detection using a faster clock signal so as to reduce the cost of testing.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a block diagram showing a configuration of a semiconductor device according to a first exemplary embodiment of the present invention;

FIG. 2 is a block diagram showing a configuration of a check signal generator;

FIG. 3 is a timing chart of the generation of a marker signal in the semiconductor device according to the first exemplary embodiment of the present invention;

FIG. 4 is a timing chart of the generation of a test result signal in the semiconductor device according to the first exemplary embodiment of the present invention;

FIG. 5 is a block diagram showing a configuration of a semiconductor device according to a second exemplary embodiment of the present invention;

FIG. 6 is a timing chart of the generation of a marker signal in the semiconductor device according to the second exemplary embodiment of the present invention; and

FIG. 7 is a block diagram showing a configuration of a semiconductor device according to a third exemplary embodiment of the present invention.

### DETAILED DESCRIPTION OF THE EXEMPLARY EMBODIMENTS

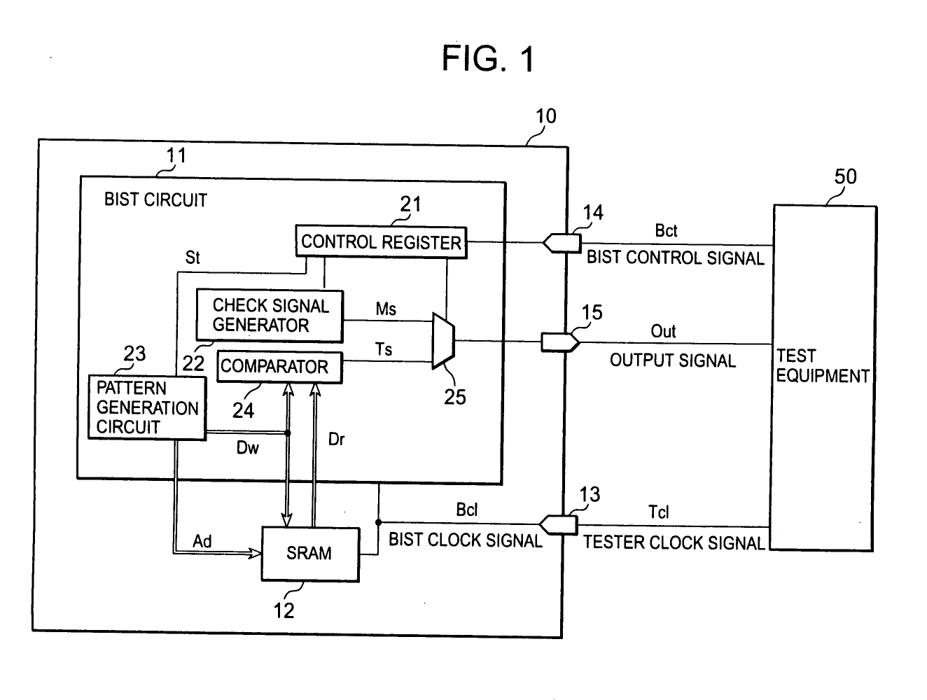

A semiconductor device according to an exemplary embodiment of the present invention includes a circuit to be tested (for example, SRAM 12 in FIG. 1), an input terminal (13 in FIG. 1) for inputting an external tester clock signal (Tc1 in FIG. 1), a built-in self-test (BIST) circuit (11 in FIG. 1) for logically testing the circuit to be tested at every cycle of the tester clock signal, and an output terminal (15 in FIG. 1) for outputting a test result signal (Ts in FIG. 1) representing a test result generated in the BIST circuit. The BIST circuit has a function of generating, before generating a test result signal, a prescribed marker signal (Ms in FIG. 1), instead of the test result signal, having a phase identical to that of the test result signal.

In the semiconductor device of the present invention, the BIST circuit may include a comparator circuit (comparator circuit 24 in FIG. 1) for comparing prescribed data read from the circuit to be tested at every cycle of the clock signal and a corresponding expected value to determine whether their relationship is a match or a non-match and may generate a marker signal to be outputted as a comparison result signal representing a non-match.

In the semiconductor device of the present invention, the circuit to be tested may be a memory circuit and the BIST circuit may be configured such that it writes data corresponding to a comparison result signal representing a comparison result “non-match” determined in the comparator circuit to a prescribed part of the memory circuit beforehand and such that it reads the data from the prescribed part of the memory circuit as a marker signal before generating a test result signal.

In the semiconductor device of the present invention, the circuit to be tested may be a memory circuit and the BIST circuit may include a marker signal generation circuit (check signal generator 22 in FIG. 1) which generates a marker signal corresponding to a prescribed part of the memory circuit.

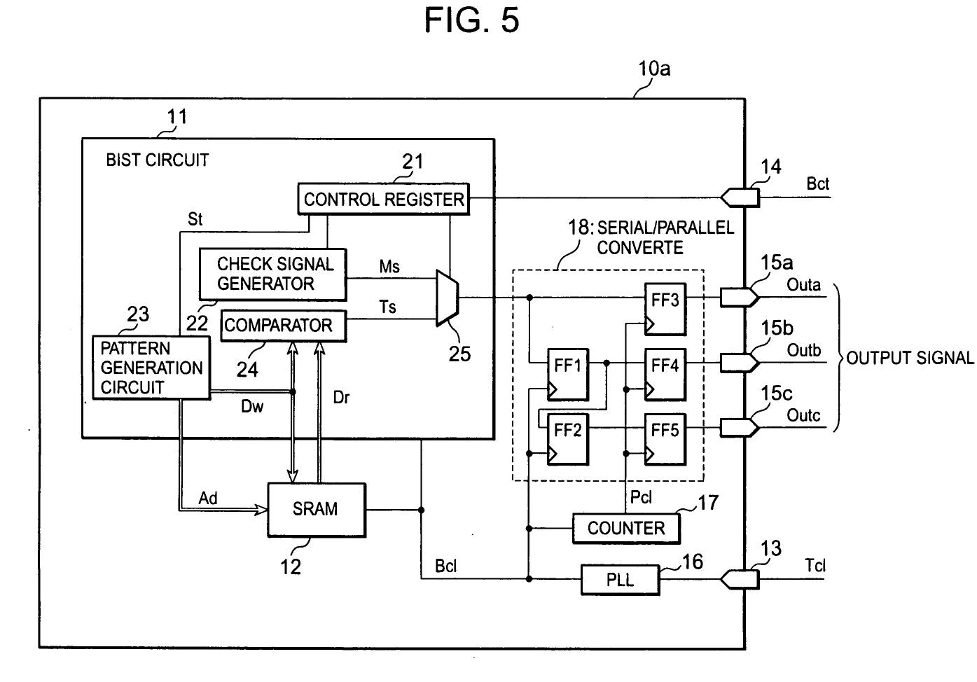

The semiconductor device of the present invention may include a clock signal generation circuit (PLL 16 in FIG. 5) for generating, in synchronization with a tester clock signal, an internal clock signal faster than the tester clock signal and a speed conversion circuit (serial/parallel converter 18 in FIG. 5) for converting the speed of a test result signal to a speed equal to the speed of the tester clock signal; and, in the semiconductor device, a BIST circuit may test a circuit to be tested at every cycle of the internal clock signal, and output terminals (15a, 15b, and 15c in FIG. 5) may output test result signals processed for speed conversion in the speed conversion circuit.

According to the semiconductor device as described above, before a test result signal is generated, a prescribed marker signal whose phase is the same as that of the test result signal is generated instead of the test result signal. This allows a test equipment (tester) connected to the semiconductor device to read the marker signal and thereby accurately determine the timing for reading the test result signal. It is, therefore, possible to successively perform checking with an expected value and faulty-cycle detection using a faster test clock signal.

In the following, exemplary embodiments of the present invention will be described in detail with reference to drawings.

### FIRST EXEMPLARY EMBODIMENT

FIG. 1 is a block diagram showing a configuration of a semiconductor device according to a first exemplary embodiment of the present invention. Referring to FIG. 1, a semiconductor device 10 includes a BIST circuit 11, an SRAM 12, input terminals 13 and 14, and an output terminal 15. The BIST circuit includes a control register 21, a check signal generator 22, a pattern generation circuit 23, a comparator 24, and a selector 25.

The semiconductor device 10 has a tester clock signal Tc1 inputted thereto from an external test equipment 50 via the input terminal 13 and supplies the inputted tester clock signal Tc1 as a BIST clock signal Bc1 to the BIST circuit 11 and the SRAM 12. The BIST circuit 11 tests the SRAM 12 in synchronization with the BIST clock signal Bc1. The SRAM 12 reads and writes data used for the test in synchronization with the BIST clock signal Bc1.

The semiconductor device 10 has a BIST control signal Bct inputted thereto from the external test equipment 50 via the input terminal 14 and supplies the inputted BIST control signal Bct to the control register 21.

In accordance with the BIST control signal Bct, the control register 21 orders the check signal generator 22 to generate, before starting a test, a prescribed marker signal Ms, instead of a test result signal Ts, whose phase is the same as that of the test result signal Ts. The control register 21 controls the selector 25 to cause the selector 25 to select the marker signal Ms and output it as an output signal Out to the external test equipment 50 via the output terminal 15. The test equipment 50 reads the marker signal Ms outputted as an output signal Out and thereby determines the timing for reading a test result signal Ts when a test is performed.

In accordance with the BIST control signal Bct, the control register 21 sends a start signal St for starting a test to the pattern generation circuit 23. The pattern generation circuit 23 generates an address signal Ad for a series of write operations and sends it to the SRAM 12 while also supplying the SRAM 12 with write data Dw. The pattern generation circuit 23 then generates an address signal Ad for a series of read operations and gives it to the SRAM 12 while supplying the comparator 24 with the data Dw written at the addresses given by the address signal Ad. The SRAM 12 reads the data Dw written according to the address signal Ad and outputs the data thus read as read data Dr to the comparator 24.

The comparator 24 compares the data Dw and the data Dr and outputs a test result signal Ts representing a test result “match” or “non-match” to the selector 25. In performing the test, the control register 21 controls the selector 25 to cause the selector 25 to select the test result signal Ts and output it as an output signal Out. The test equipment 50 reads the test result signal Ts outputted as the output signal Out and determines if the SRAM 12 has a faulty part.

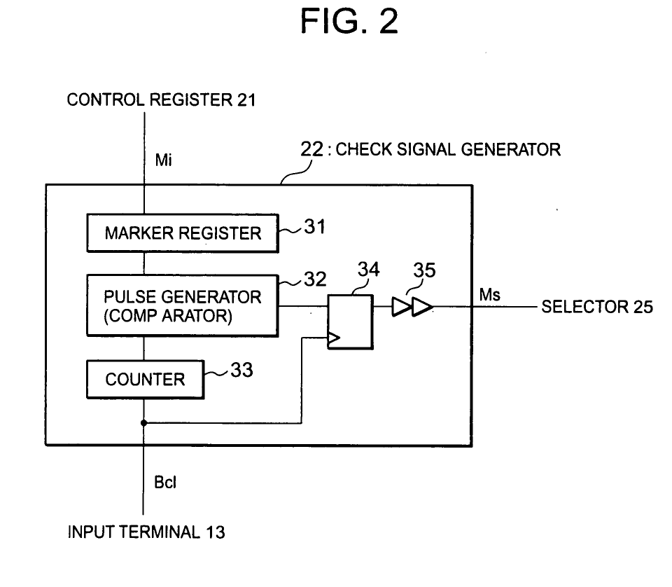

The check signal generator 22 will be described in detail below. FIG. 2 is a block diagram showing a configuration of the check signal generator 22. The check signal generator 22 includes a marker register 31, a pulse generator 32, a counter 33, a latch circuit 34, and a delay buffer 35.

The marker register 31 inputs, before starting a test, mark position data Mi from the control register 21 and holds it. The mark position data Mi represents a count value for generating a marker pulse in the marker signal Ms. The counter 33 counts, after a test is started, the number of clock pulses of the BIST clock signal Bc1. The pulse generator 32 compares the data from the control register 21 and the number of clock pulses counted by the counter 33 and, when they match, outputs a pulse to the latch circuit 34. The latch circuit 34 latches the pulse based on the BIST clock signal Bc1 and outputs the result of latching as a marker signal Ms to the selector 25 via the delay buffer 35. The delay buffer 35 delays the outputting of the marker signal Ms by an amount of time equivalent to the time used in reading data from the SRAM 12 and performing data comparison in the comparator 24.

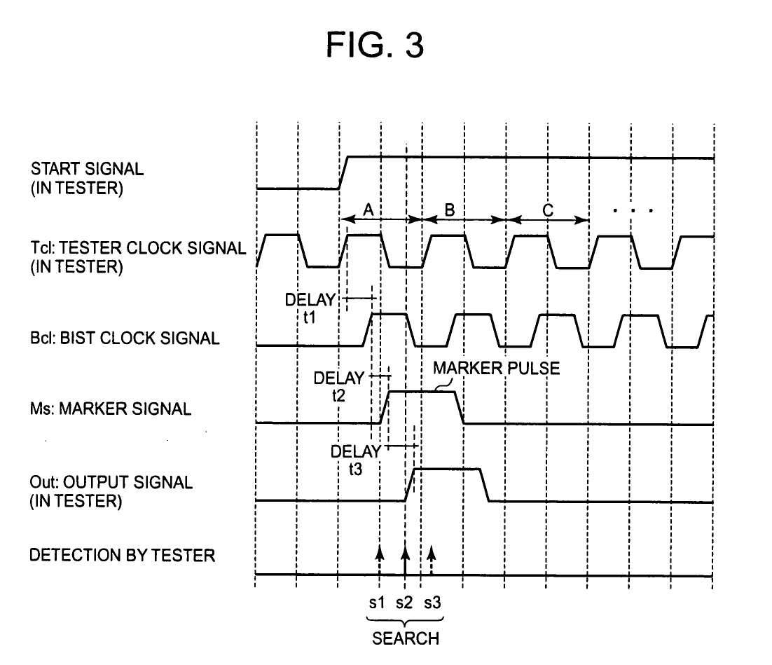

The generation of a marker signal Ms by the check signal generator 22 will be described in the following. FIG. 3 is a timing chart of the generation of a marker signal Ms in the semiconductor device 10. Referring to FIG. 3, testing by the BIST circuit starts in the cycle in which a start signal rises (in the tester). The start signal is included in the BIST control signal Bct that is supplied to the control register 21. The control register 21 is also supplied with the BIST clock signal so as to enable timing synchronization in the BIST circuit 11.

The tester clock signal Tc1 is delayed by t1 to be used as the BIST clock signal Bc1. The delay t1 is caused mainly by the wiring between the test equipment 50 and the semiconductor device 10. It is after the start signal is activated that the BIST clock signal Bc1 is practically supplied in the BIST circuit 11.

The check signal generator 22 outputs, after the BIST clock signal Bc1 is practically supplied and a delay t2 is generated, a marker pulse to the marker signal Ms. In the present example, the marker pulse is generated during the phase A period of the tester clock signal. The marker pulse is delayed by t3 before being outputted as an output signal Out to the test equipment 50.

The test equipment 50 searches for an active (high level) marker pulse at different timings (s1, s2, and s3) and selects timing s3, which allows the marker pulse to be reliably detected, as the timing for collecting the output signal Out.

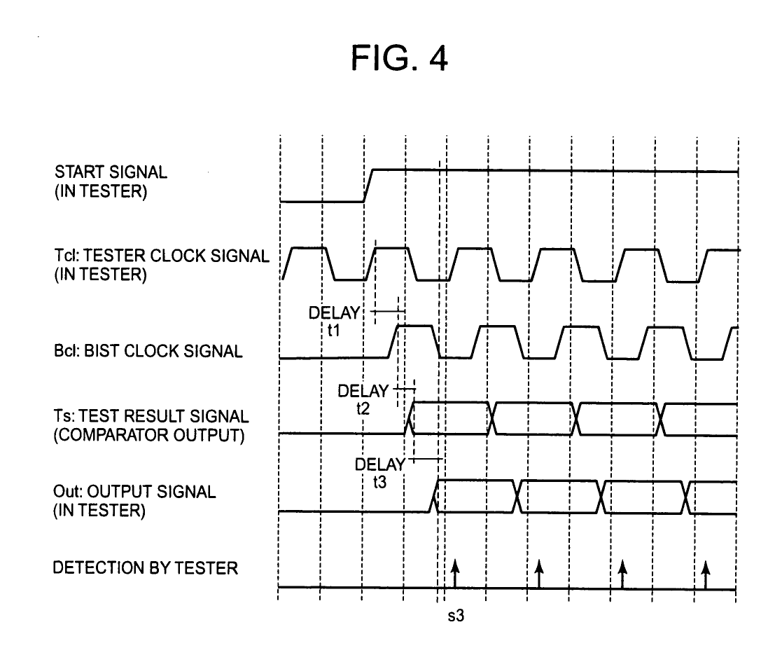

The generation of a test result signal Ts by the comparator 24 will be described in the following. FIG. 4 is a timing chart of the generation of a test result signal Ts in the semiconductor device 10. The tester clock signal Tc1 is delayed by t1 to be used as the BIST clock signal Bc1. The operation up to this step is the same as described above with reference to FIG. 3 for the generation of a marker signal Ms.

The comparator 24 outputs, after the BIST clock signal Bc1 is practically supplied and a delay t2 is generated, a test result signal Ts. The test result signal Ts is delayed by t3 before being outputted as an output signal Out to the test equipment 50.

The test equipment 50 reads, at the timing s3 previously selected in generating a marker signal Ms, the output signal Out and determines if the SRAM 12 has a faulty part.

As described above, before generating a test result signal Ts, the BIST circuit 11 generates, instead of the test result signal Ts, a prescribed marker signal Ms whose phase is the same as that of the test result signal Ts. The test equipment 50 connected to the semiconductor device 10 can, therefore, accurately determine the timing for collecting the test result signal Ts by reading the marker signal Ms. This makes it possible, even in cases where the tester clock signal Tc1 is made faster, to check the SRAM 12 on a stable basis and reduce the time required to perform the test.

### SECOND EXEMPLARY EMBODIMENT

FIG. 5 is a block diagram showing a configuration of a semiconductor device according to a second exemplary embodiment of the present invention. In FIG. 5, components identical to those shown in FIG. 1 are assigned the same reference numerals as in FIG. 1 and their descriptions are omitted. A semiconductor device 10a shown in FIG. 5 is like the semiconductor device 10 shown in FIG. 1 additionally including a PLL 16, a counter 17, and a serial/parallel converter 18.

The PLL 16 generates a BIST clock signal Bc1 by multiplying a tester clock signal Tc1 (by three in the present example) and supplies the BIST clock signal Bc1 thus generated to a BIST circuit 11, an SRAM 12, a counter 17, and a serial/parallel converter 18.

The counter 17 frequency-divides the BIST clock signal Bc1 (by three in the present example) and supplies the resultant signal as a collection signal Pei to the serial/parallel converter 18.

The serial/parallel converter 18 includes flip-flop circuits FF1 to FF5. The flip-flop circuits FF1 and FF2 shift the marker signal Ms or the test result signal Ts outputted from the selector 25 based on the BIST clock signal Bc1. The flip-flop circuits FF3, FF4, and FF5 latch, according to the collection signal Pc1, the signals outputted from the selector 25 and the flip-flop circuits FF1 and FF2 and output the signals thus latched as output signals Outa, Outb, and Outc to the test equipment 50 via output terminals 15a, 15b, and 15c, respectively. The serial/parallel converter 18 functions as a speed conversion circuit and outputs the marker signal Ms or the test result signal Ts as a parallel signal to the test equipment 50.

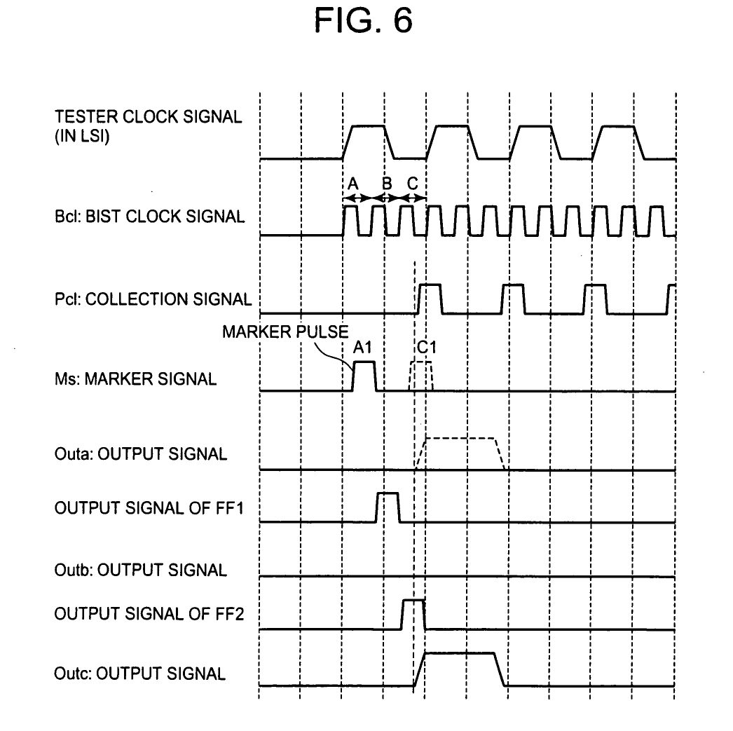

The generation of a marker signal Ms by the check signal generator 22 will be described in the following. FIG. 6 is a timing chart of the generation of a marker signal Ms in the semiconductor device 10a. Referring to FIG. 6, the marker signal Ms is outputted in synchronization with the BIST clock signal Bc1. The operation up to this step is the same as described above with reference to FIG. 3. Namely, a marker pulse corresponding to the phase A period of the BIST clock signal Bc1 is outputted as a marker signal Ms at position A1 from the selector 25. When the marker pulse corresponds to the phase C period of the BIST clock signal Bc1, the marker pulse is outputted as a marker signal Ms at position C1 from the selector 25. The marker pulse is shifted at flip-flop circuits FF1 and FF2. The signals outputted from the selector 25 and the flip-flop circuits FF1 and FF2 are latched by the flip-flop circuits FF3, FF4, and FF5, respectively, according to a collection signal Pc1. The signals thus latched are outputted as output signals Outa, Outb, and Outc, respectively, to the test equipment 50.

As described above, the semiconductor device 10a provided with the serial/parallel converter 18 can output test results to the test equipment 50 at low speed. In this case, the test equipment 50 connected to the semiconductor device 10a can accurately determine the timing for collecting the test result signal Ts by reading the marker signal Ms as the output signal Outa, Outb, or Outc.

### THIRD EXEMPLARY EMBODIMENT

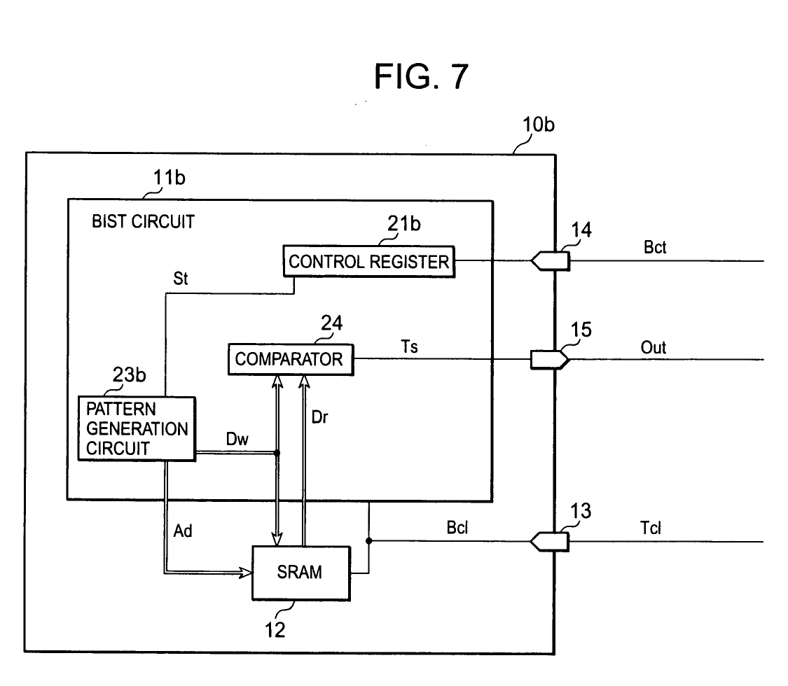

FIG. 7 is a block diagram showing a configuration of a semiconductor device according to a third exemplary embodiment of the present invention. In FIG. 7, components identical to those shown in FIG. 1 are assigned the same reference numerals as in FIG. 1 and their descriptions are omitted. A semiconductor device 10b shown in FIG. 7 is like the semiconductor device 10 shown in FIG. 1 less the check signal generator 22 and the selector 25.

A pattern generation circuit 23b writes data for fault detection to an address to be a target of marker pulse generation of an SRAM 12. A comparator 24 detects the data for fault detection and outputs a marker pulse to a test result signal Ts. Namely, the control register 21b makes the pattern generation circuit 23b generate, before generating a test result signal, a prescribed marker pulse whose phase is the same as that of the test result signal. The test equipment 50 can accurately determine, like in the first exemplary embodiment, the timing for collecting the test result signal Ts by reading an output signal Out and determining the position of the marker pulse.

The disclosures of the foregoing patent documents are incorporated herein by reference. The above exemplary embodiments or examples of the present invention can be changed and adjusted within the framework and based on the basic technical concept of the present disclosure (inclusive of the appended claims) of the invention. Also within the framework of the scope of claims of the invention, disclosed elements can be combined in various ways or adopted selectively. Namely, the invention is inclusive of various modifications and alterations which can be devised by people with ordinary skill in the art within the framework and based on the basic technical concept of the whole disclosure, inclusive of the appended claims, of the invention.

Further, it is noted that Applicant's intent is to encompass equivalents of all claim elements, even if amended later during prosecution.

What is claimed is:

1. A semiconductor device, comprising:
a plurality of circuits to be tested;
a plurality of input terminals each of which receives a tester clock signal for the respective circuits;
a built-in self-test circuit which logically tests the circuit to be tested at every cycle of the tester clock signal; and
an output terminal for outputting a test result signal representing a result of testing performed by the built-in self-test circuit,
wherein the built-in self-test circuit generates, before generating the test result signal, a marker signal having a phase identical to a phase of the test result signal.

2. The semiconductor device according to claim 1,
wherein the built-in self-test circuit includes a comparator circuit which, at every cycle of the tester clock signal, compares a data read from the circuit to be tested and a corresponding expected value, to determine whether the result of a comparison is a match or a non-match, and
wherein the built-in self-test circuit generates a signal corresponding to the comparison result signal representing a non-match as a result of the comparison performed by the comparator circuit for use as the marker signal.

3. The semiconductor device according to claim 2,
wherein the circuit to be tested comprises a memory circuit, and
wherein the built-in self-test circuit writes a data corresponding to the comparison result signal representing a non-match as a result of the comparison performed by the comparator circuit to a predetermined memory part of the memory circuit in advance, and reads the data from the predetermined memory part for use as the marker signal before generating the test result signal.

4. The semiconductor device according to claim 2,
wherein the circuit to be tested comprises a memory circuit, and
wherein the built-in self-test circuit includes a marker signal generation circuit which generates the marker signal corresponding to a predetermined memory part of the memory circuit.

5. The semiconductor device according to claim 1, further comprising:
a clock signal generation circuit which generates, in synchronization with the tester clock signal, an internal clock signal faster than the tester clock signal, and
a speed conversion circuit which converts a speed of the test result signal to a speed equal to a speed of the external tester clock signal;
wherein the built-in self-test circuit tests the circuit to be tested at every cycle of the internal clock signal, and
wherein the output terminal outputs a test result signal processed for speed conversion by the speed conversion circuit.

6. A method of testing a semiconductor device, the semiconductor device including a built-in self-test circuit for testing a circuit to be tested in synchronization with a tester clock signal inputted from an outside and outputting a test result signal representing a result of testing performed in the built-in self-test circuit to the outside, the method comprising:
before generating the test result signal, generating a marker signal having a phase identical to a phase of the test result signal, instead of the test result signal in the built-in self-test circuit.

7. A method of testing a semiconductor device, the semiconductor device including a circuit to be tested; an input terminal for receiving a tester clock signal from a test equipment; a built-in self-test circuit for logically testing the circuit to in synchronization with the tester clock signal; and an output terminal for outputting a test result signal representing a result of testing performed by the built-in self-test circuit, the method comprising:
supplying the tester clock signal to the input terminal from the test equipment;
before generating the test result signal, generating a marker signal having a phase identical to a phase of the test result signal, by the built-in self-test circuit; and
receiving the marker signal from the output terminal and determining a phase of the test result signal, by the test equipment.

8. A built-in self-test circuit, comprising:
a control register;
a pattern generation circuit which generates a test pattern based on a first information from the control register;
a marker signal generator which generates a marker signal based on a second information from the control register;
a comparator which compares the test pattern with a data read from a circuit and outputs a comparison result, the comparison result having a phase substantially identical to a phase of the marker signal; and
a selector which selectively outputs the marker signal or the comparison result based on a third information from the control register.

9. The built-in self-test circuit as claimed in claim 8, wherein the marker signal generator includes:
a marker register which stores the second information;
a counter which counts a clock; and
a pulse generator which outputs a pulse corresponding to the marker signal when a counting number of the counter is coincident with the second information.
